(19) United States
(12) Patent Application Publication
(10) Pub. No.: US 2019/0023860 A1
(43) Pub. Date: Jan. 24, 2019

(54) COMPOSITION FOR WINDOW FILM, FLEXIBLE WINDOW FILM FORMED THEREFROM, AND DISPLAY DEVICE COMPRISING SAME

(71) Applicants: SAMSUNG SDI CO., LTD., Yongin-si, Gyeonggi-do (KR); SAMSUNG ELECTRONICS CO., LTD., Suwn-si, Gyeonggi-do (KR)

(72) Inventors: Min Hye KIM, Suwon-si (KR); Kyoung Ku KANG, Suwon-si (KR); Ji Hwan PARK, Suwon-si (KR); Chang Soo WOO, Suwon-si (KR); Ji Sun IM, Suwon-si (KR); Seung Woo JANG, Suwon-si (KR); Jin Hee CHOI, Suwon-si (KR); Dong Il HAN, Suwon-si (KR)

(73) Assignees: Samsung SDI Co., Ltd., Yongin-si, Gyeonggi-do (KR); Samsung Electronics Co., Ltd., Suwon-si, Gyeonggi-do (KR)

(21) Appl. No.: 16/070,763

(22) PCT Filed: Oct. 7, 2016
(86) PCT No.: PCT/KR2016/011231

§ 371 Date: Jul. 17, 2018

(30) Foreign Application Priority Data
Jan. 22, 2016 (KR) 10-2016-0008413

(51) Int. Cl. C08J 5/18; C09D 7/63; C09D 183/04; C08J 7/04; G09F 9/30; G06F 3/041; H01L 51/52

(52) U.S. Cl. CPC C08J 5/18; C09D 7/63; C09D 183/04; C08J 7/047; C08K 5/1515; G06F 3/0412; H01L 51/5246; H01L 51/5281; G09F 9/301

(57) ABSTRACT

Provided are a siloxane resin of chemical formula 1, a composition for a window film, the composition containing a cross-linking agent and an initiator, a flexible window film formed therefrom, and a flexible display device comprising the same.

### CROSS-REFERENCE TO RELATED APPLICATION(S)

This application is a National Phase patent application and claims priority to and the benefit of International Application Number PCT/KR2016/011231, filed on Oct. 7, 2016, which claims priority to and the benefit of Korean Patent Application No. 10-2016-0008413, filed on Jan. 22, 2016, the entire contents of each of which are incorporated herein by reference.

### TECHNICAL FIELD

The present invention relates to a composition for window films, a flexible window film formed of the same, and a flexible display including the same.

### BACKGROUND ART

Recently, with replacement of a glass substrate or a high hardness substrate with a film in a display, flexible displays capable of being folded and unfolded have been developed. Since a flexible display is thin and light, has high impact resistance, and can be folded and unfolded, the flexible display can be manufactured in various shapes. Various optical devices in the flexible display are required to exhibit good flexibility and a low inverse radius of curvature based on usefulness. In addition, since a window film is disposed at the outermost side of a display, the window film is required to have high hardness and to be free from indentation when pressed by the hand or the like.

The background technique of the present invention is disclosed in Japanese Patent Publication No. 2007-176542.

### SUMMARY

It is one aspect of the present invention to provide a composition for window films, which can realize a flexible window film having high hardness, good flexibility, low inverse radius of curvature and low curl and being free from indentation, and has high curing rate.

It is another aspect of the present invention to provide a flexible window film which has high hardness, good flexibility, low inverse radius of curvature and low curl and being free from indentation, and a display including the same.

In accordance with one aspect of the present invention, a composition for window films includes: a siloxane resin represented by Formula 1; a crosslinking agent; and an initiator:

(R¹SiO_{3/2})ₓ(R²SiO_{3/2})_{y}(SiO_{4/2})_{z} <Formula 1>

(wherein Formula 1, R¹ and R² are as defined in the following detailed description of the present invention; and x, y and z are set to satisfy about 0.30≤x≤about 0.90, about 0.01≤y≤about 0.50, about 0.01≤z≤about 0.40, and x+y+z=1).

In accordance with another aspect of the present invention, a flexible window film includes: a base layer and a coating layer formed on one surface of the base layer, wherein the coating layer is formed of a composition comprising a siloxane resin represented by Formula A and has a pencil hardness of about 6H or higher and a radius of curvature of about 5.0 mm or less:

(R¹SiO_{3/2})x(R²SiO_{3/2})y(SiO_{4/2})z <Formula A>

(wherein Formula A, R¹ and R² are as defined in the following detailed description of the present invention, and x, y and z satisfy 0<x<1, 0<y<1, 0<z<1, x+y+z=1).

In accordance with a further aspect of the present invention, a flexible display includes the flexible window film set forth above.

The present invention provides a composition for window films, which can realize a flexible window film having high hardness, good flexibility, low inverse radius of curvature and low curl and being free from indentation, and has high curing rate.

The present invention provides a flexible window film, which has high hardness, good flexibility, low inverse radius of curvature and low curl and being free from indentation, and a display including the same.

### BRIEF DESCRIPTION OF THE DRAWINGS

FIG. 1 is a sectional view of a flexible window film according to one embodiment of the present invention.

FIG. 2 is a sectional view of a flexible window film according to another embodiment of the present invention.

FIG. 3 is a sectional view of a flexible display according to one embodiment of the present invention.

FIG. 4 is a sectional view of one embodiment of a display part shown in FIG. 3.

FIG. 5 is a sectional view of a flexible display according to another embodiment of the present invention.

FIG. 6 is a sectional view of a flexible display according to a further embodiment of the present invention.

FIG. 7 is a schematic diagram illustrating measurement of curling.

### DETAILED DESCRIPTION

Embodiments of the present invention will be described in detail with reference to the accompanying drawings. It should be understood that the present invention may be embodied in different ways and is not limited to the following embodiments. In the drawings, portions irrelevant to the description will be omitted for clarity. Like components will be denoted by like reference numerals throughout the specification.

As used herein, spatially relative terms such as “upper” and “lower” are defined with reference to the accompanying drawings. Thus, it will be understood that the term “upper surface” can be used interchangeably with the term “lower surface”. When an element or layer is referred to as being disposed “on” another element or layer, it can be directly disposed on the other element or layer or intervening elements or layers may be present. However, when an element or layer is referred to as being “directly disposed on” another element or layer, there are no intervening elements or layers present.

Herein, unless otherwise stated, the term “substituted” means that at least one hydrogen atom in a functional group is substituted with a hydroxyl group, an unsubstituted C₁ to C₁₀ alkyl group, a C₁ to C₁₀ alkoxy group, a C₃ to C₁₀ cycloalkyl group, an unsubstituted C₆ to C₂₀ aryl group, a C₇ to C₂₀ arylalkyl group, a benzophenone group, a C₆ to C₂₀ aryl group substituted with a C₁ to C₁₀ alkyl group, or a C₁, to C₁₀ alkyl group substituted with a C₁ to C₁₀ alkoxy group. The term “alicyclic epoxy group” means an epoxidized C₄ to C₂₀ cycloalkyl group and the term “alicyclic epoxy group-containing functional group” means an alicyclic epoxy group-containing C₁ to C₁₂ alkyl group or an alicyclic epoxy group-containing C₅ to C₂₀ cycloalkyl group. The term “glycidyl group-containing functional group” refers to a glycidoxy group, a glycidyl group or glycidoxy group-containing C₁ to C₂₀ alkyl group, or a glycidyl group or glycidoxy group-containing C₅ to C₂₀ cycloalkyl group. As used herein, “halogen” refers to fluorine, chlorine, bromine or iodine.

Herein, “Ec” denotes a 2-(3,4-epoxycyclohexyl)ethyl group and “Gp” denotes a 3-glycidoxypropyl group.

Hereinafter, a composition for window films according to one embodiment of the present invention will be described.

A composition for window films according to this embodiment may include a siloxane resin represented by Formula 1, a crosslinking agent, and an initiator:

(R¹SiO_{3/2})ₓ(R²SiO_{3/2})_{y}(SiO_{4/2})_{z} <Formula 1>

(wherein Formula 1, R¹ is an alicyclic epoxy group or an alicyclic epoxy group-containing functional group, R² is a glycidyl group or a glycidyl group-containing functional group, and x, y and z are set to satisfy about 0.30≤x≤about 0.90, about 0.01≤y≤about 0.50, about 0.01≤z≤about 0.40, and x+y+z=1).

The siloxane resin of Formula 1 can improve curability of the composition for window films. In Formula 1, the component represented by (R¹SiO_{3/2})ₓ can improve hardness of a window film formed of the composition, the component represented by (R²SiO_{3/2})_{y} can improve flexibility of the window film, and (SiO_{4/2})_{z} can prevent decrease in hardness of the window film due to (R²SiO_{3/2})_{y} while reducing the inverse radius of curvature thereof. Accordingly, the siloxane resin of Formula 1 can provide good hardness and flexibility to the window film while reducing the inverse radius of curvature. Specifically, in Formula 1, R¹ may be a (3,4-epoxycyclohexyl)methyl group, a (3,4-epoxycyclohexyl)ethyl group, a (3,4-epoxycyclohexyl)propyl group, and the like. In Formula 1, R² may be a glycidoxy propyl group. In Formula 1, x, y and z may be in the range of about 0.40≤x≤about 0.85, about 0.05≤y≤about 0.50, and about 0.01≤z≤about 0.35, more specifically about 0.40≤x≤about 0.70, about 0.20≤y≤about 0.40, and about 0.05≤z≤about 0.35. For example, x, y and z may be in the range of about 0.05≤y≤about 0.50, about 0.05≤y≤about 0.40, about 0.05≤y≤about 0.30, about 0.01≤z≤about 0.30, about 0.05≤z≤about 0.35, about 0.10≤z≤about 0.35, about 0.10≤z≤about 0.30. Within these ranges, the window film can have high hardness, good flexibility and low inverse radius of curvature, and can be free from indentation. The compound for window films according to this embodiment may include at least one siloxane resin represented by Formula 1.

Specifically, the siloxane resin of Formula 1 may be a compound represented by Formula 1-1:

(EcSiO_{3/2})ₓ(GpSiO_{3/2})_{y}(SiO_{4/2})_{z} <Formula 1-1>

(wherein Formula 1-1, x, y and z are as defined in Formula 1).

The siloxane resin of Formula 1 may have a weight average molecular weight of about 4,000 to about 100,000, specifically about 4,500 to about 15,000, for example, about 4,000, about 4,500, about 5,000, about 5,500, about 6,000, about 6,500, about 7,000, about 7,500, about 8,000, about 8,500, about 9,000, about 9,500, about 10,000, about 10,500, about 11,000, about 11,500, about 12,000, about 12,500, about 13,000, about 13,500, about 14,000, about 14,500, or about 15,000. Within this range, the siloxane resin can be easily prepared and the window film formed of the composition has good properties in terms of hardness and flexibility, low inverse radius of curvature and low curl. The siloxane resin of Formula 1 may have a polydispersity index (PDI) of about 1.0 to about 3.5, specifically about 1.5 to about 3.0, and an epoxy equivalent weight of about 0.1 mol/100 g to about 1.0 mol/100 g, specifically about 0.3 mol/100 g to about 0.7 mol/100 g. When the polydispersity index and epoxy equivalent of the siloxane resin fall within these ranges, the composition for window films can exhibit stable coating properties while maintaining hardness and flexural properties of the window film.

The crosslinking agent is cured together with the siloxane resin represented by Formula 1 and can increase hardness of the window film. The crosslinking agent contains a crosslinkable functional group, for example, an epoxy group or an oxetane group and may further contain at least one of a non-cyclic aliphatic hydrocarbon group, a cyclic aliphatic hydrocarbon group, an aromatic hydrocarbon group, and a hydrogenated aromatic hydrocarbon group to further improve flexibility of the window film. Specifically, the crosslinking agent may include at least one of a non-cyclic aliphatic epoxy monomer, a cyclic aliphatic epoxy monomer, an aromatic epoxy monomer, a hydrogenated aromatic epoxy monomer, and an oxetane monomer. The compound for window films according to this embodiment may include at least one crosslinking agent.

Examples of the non-cyclic aliphatic epoxy monomer may include 1,4-butanediol diglycidyl ether, 1,6-hexanediol diglycidyl ether, neopentyl glycol diglycidyl ether, trimethylolpropane triglycidyl ether, polyethylene glycol diglycidyl ether, glycerin triglycidyl ether, polypropylene glycol diglycidyl ether; polyglycidyl ethers of polyether polyols obtained by adding one or more alkylene oxides to aliphatic polyhydric alcohols, such as ethylene glycol, propylene glycol, glycerin, and the like; diglycidyl esters of aliphatic long-chain dibasic acids; diglycidyl esters of aliphatic long-chain dibasic acids; monoglycidyl ethers of higher aliphatic alcohols; glycidyl ethers of higher fatty acids; epoxidized soybean oil; butyl epoxy stearate; octyl epoxy stearate; epoxidized linseed oil; and epoxidized polybutadiene.

The cyclic aliphatic epoxy monomer is a compound having at least one epoxy group in an alicyclic group. Specifically, the cyclic aliphatic epoxy monomer may include alicyclic epoxy carboxylates, alicyclic epoxy (meth)acrylates, and the like. More specifically, the cyclic aliphatic epoxy monomer may include 3,4-epoxycyclohexyl)methyl-3′,4′-epoxycyclohexanecarboxylate, diglycidyl 1,2-cyclohexanedicarboxylate, 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexylmethyl-3′,4′-epoxy-6′-methylcyclohexanecarboxylate, ε-caprolactone modified 3,4-epoxycyclohexylmethyl-3′,4′-epoxy-cyclohexanecarboxylate, trimethylcaprolactone modified 3,4-epoxycyclohexylmethyl-3′,4′-epoxycyclohexanecarboxylate, β-methyl-δ-valerolactone modified 3,4-epoxycyclohexylmethyl-3′,4′-epoxycyclohexanecarboxylate, 1,4-cyclohexanedimethanol bis(3,4-epoxycyclohexanecarboxylate, ethylene glycol di(3,4-epoxycyclohexylmethyl)ether, ethylenebis(3,4-epoxycyclohexanecarboxylate), 3,4-epoxycyclohexylmethyl(meth)acrylate, bis(3,4-epoxycyclohexylmethyl)adipate, 4-vinylcyclohexen dioxide, vinylcyclohexene monoxide, and the like.

Examples of the aromatic epoxy monomer may include bisphenol type epoxy resins such as diglycidyl ether of bisphenol A, diglycidyl ether of bisphenol F, and diglycidyl ether of bisphenol S; novolac type epoxy resins such as a phenol novolac epoxy resin, a cresol novolac epoxy resin, and a hydroxybenzaldehyde phenol novolac epoxy resin; polyfunctional epoxy resins, such as glycidyl ether of tetrahydroxyphenylmethane, glycidyl ether of tetrahydroxybenzophenone, and epoxidized polyvinyl phenol.

The hydrogenated aromatic epoxy monomer is a compound obtained by selective hydrogenation of an aromatic epoxy monomer in the presence of a catalyst under pressure. The aromatic epoxy monomer for the hydrogenated aromatic epoxy monomer may include the aromatic epoxy monomers described above.

The oxetane monomer may include at least one of 3-methyloxetane, 2-methyloxetane, 2-ethylhexyloxetane, 3-oxetanol, 2-methyleneoxetane, 3,3-oxetanedimethanethiol, 4-(3-methyloxetan-3-yl)benzonitrile, N-(2,2-dimethylpropyl)-3-methyl-3-oxetanmethaneamine, N-(1,2-dimethylbutyl)-3-methyl-3-oxetanmethaneamine, (3-ethyloxetan-3-yl)methyl (meth)acrylate, 4-[(3-ethyloxetan-3-yl)methoxy]butan-1-ol, 3-ethyl-3-hydroxymethyloxetane, xylenebisoxetane, and 3-[ethyl-3[[(3-ethyloxetane-3-yl]methoxy]methyl]oxetane, without being limited thereto.

The crosslinking agent may be present in an amount of about 0.1 parts by weight to about 50 parts by weight, specifically about 1 part by weight to about 30 parts by weight, more specifically about 5 parts by weight to about 20 parts by weight, for example, about 5 parts by weight, about 6 parts by weight, about 7 parts by weight, about 8 parts by weight, about 9 parts by weight, about 10 parts by weight, about 11 parts by weight, about 12 parts by weight, about 13 parts by weight, about 14 parts by weight, about 15 parts by weight, about 16 parts by weight, about 17 parts by weight, about 18 parts by weight, about 19 parts by weight, about 20 parts by weight, about 21 parts by weight, about 22 parts by weight, about 23 parts by weight, about 24 parts by weight, about 25 parts by weight, about 26 parts by weight, about 27 parts by weight, about 28 parts by weight, about 29 parts by weight, or about 30 parts by weight, relative to 100 parts by weight of the siloxane resin of Formula 1. Within this range, the crosslinking agent can improve flexibility and hardness of the window film.

The initiator serves to cure the siloxane resin represented by Formula 1 and the crosslinking agent and may include at least one of a photocationic initiator and a photoradical initiator. The photocationic initiator may include any suitable photocationic initiator known to those skilled in the art. Specifically, the photocationic initiator may be an onium salt including a cation and an anion. Examples of the cation may include: diaryliodoniums such as diphenyliodonium, 4-methoxydiphenyliodonium, bis(4-methylphenyl)iodonium, bis(4-tert-butylphenyl)iodonium, bis(dodecylphenyl)iodonium, and (4-methylphenyl)[(4-(2-methylpropyl)phenyl)iodonium]; triarylsulfoniums such as triphenylsulfonium, diphenyl-4-thiophenylphenylsulfonium, and diphenyl-4-thiophenoxyphenylsulfonium; and bis[4-(diphenylsulfonio)phenyl]sulfide. Examples of the anion may include hexafluorophosphate (PF₆⁻), tetrafluoroborate (BF₄⁻), hexafluoroantimonate (SbF₆⁻), hexafluoroarsenate (AsF₆⁻), and hexachloroantimonate (SbCl₆⁻). As the photoradical initiator, any photoradical initiator known to those skilled in the art may be used. Specifically, the photoradical initiator may include at least one of thioxanthone, phosphorus, triazine, acetophenone, benzophenone, benzoin, and oxime photoradical initiators. The initiator may be present in an amount of about 0.01 parts by weight to about 20 parts by weight, specifically about 1 part by weight to about 5 parts by weight, relative to 100 parts by weight of the siloxane resin of Formula 1. Within this range, the siloxane resin can be sufficiently cured without deterioration in transparency of the window film due to remaining initiator.

The composition for window films according to this embodiment may further include nanoparticles. The nanoparticles can further improve hardness of the window film. The nanoparticles may include at least one of silica, aluminum oxide, zirconium oxide, and titanium oxide, without being limited thereto. The nanoparticles are not limited to a particular shape or size. Specifically, the nanoparticles may include spherical, flake, or amorphous particles. The nanoparticles may have an average particle size of 1 nm to 200 nm, specifically 10 nm to 50 nm. Within this range, the nanoparticles can increase hardness of the window film without affecting surface roughness and transparency of the window film. A portion or the entirety of surfaces of the nanoparticles may be subjected to surface treatment with a silicone compound for mixing with the siloxane resin. The nanoparticles may be present in an amount of about 0.1 parts by weight to about 60 parts by weight, specifically about 10 parts by weight to about 50 parts by weight, 100 parts by weight of the siloxane resin of Formula 1. Within this range, the nanoparticles can increase hardness of the window film without affecting surface roughness and transparency thereof.

The composition for window films according to this embodiment may further include additives. The additives can provide additional functions to a window film. The additives may include any typical additives used for window films in the related art. Specifically, the additives may include at least one of a UV absorbent, a reaction inhibitor, an adhesion promoter, a thixotropic agent, a conductivity imparting agent, a color adjusting agent, a stabilizer, an antistatic agent, an antioxidant, and a leveling agent, without being limited thereto. The reaction inhibitor may include ethynylcyclohexane. The adhesion promoter may include an epoxy group or an alkoxysilyl group-containing silane compound. The thixotropic agent may include fumed silica and the like. The conductivity imparting agent may include a metal powder such as silver powder, copper powder, or aluminum powder. The color adjusting agent may include pigments, dyes, and the like. The UV absorber can increase light resistance of the window film. The UV absorber may include any typical UV absorber known to those skilled in the art. Specifically, the UV absorbent may include at least one of triazine, benzimidazole, benzophenone, and benzotriazole UV absorbents, without being limited thereto. The additives may be present in an amount of about 0.01 parts by weight to about 5 parts by weight, specifically about 0.1 parts by weight to about 2.5 parts by weight, relative to 100 parts by weight of the siloxane resin of Formula 1. Within this range, the additives can improve hardness and flexibility of the window film while realizing inherent effects thereof.

The composition for window films according to this embodiment may further include a solvent to improve coatability, wettability or processability. The solvent may include methylethylketone, methylisobutylketone, and propylene glycol monomethyl ether acetate, without being limited thereto.

The composition for window films according to this embodiment may have a viscosity of about 50 cP to 2,000 cP at 25° C. Within this range, the composition allows easy formation of the window film.

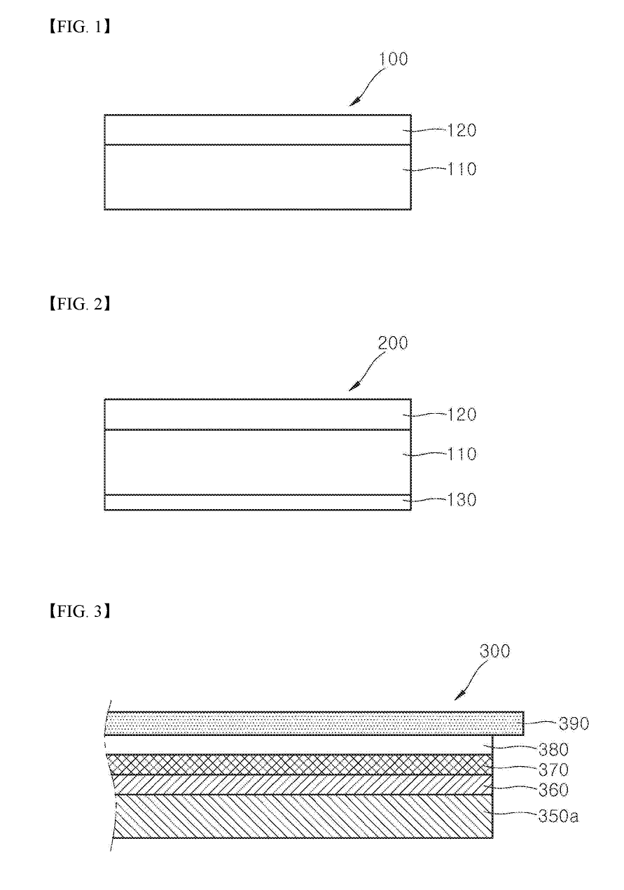

Next, a flexible window film according to one embodiment will be described with reference to FIG. 1. FIG. 1 is a sectional view of a flexible window film according to one embodiment of the invention.

Referring to FIG. 1, a flexible window film 100 according to this embodiment includes a base layer 110 and a coating layer 120, wherein the coating layer 120 may be formed of a composition including the siloxane resin represented by Formula A:

(R¹SiO_{3/2})ₓ(R²SiO_{3/2})_{y}(SiO_{4/2})_{z} <Formula A>

(wherein Formula A, R¹, R² and R³ are as defined in Formula 1; and x, y and z are set to satisfy 0<x<1, 0<y<1, 0<z<1, and x+y+z=1).

The base layer 110 can improve mechanical strength of the flexible window film 100 by supporting the flexible window film 100 and the coating layer 120. The base layer 110 may be attached to a display part, a touchscreen panel, or a polarizing plate through an adhesive layer or the like. The base layer 110 may be formed of an optically clear flexible resin. For example, the optically clear flexible resin may include at least one of polyester resins such as polyethylene terephthalate, polyethylene naphthalate, polybutylene terephthalate, and polybutylene naphthalate, polycarbonate resins, polyimide resins, polystyrene resins, and poly(meth)acrylate resins, such as poly(methyl methacrylate). The base layer 110 may have a thickness of about 10 μm to about 200 μm, specifically about 20 μm to about 150 μm, more specifically about 50 μm to about 100 μm. Within this range, the base layer can be used in the flexible window film.

The coating layer 120 may be formed on the base layer 110 to protect the base layer 110 and the display part, the touchscreen panel or the polarizing plate, and has high flexibility and high hardness to be used for a flexible display. The coating layer 120 may have a thickness of about 5 μm to about 100 μm, specifically about 10 μm to about 80 μm. Within this range, the coating layer can be used in the flexible window film. Although not shown in FIG. 1, functional surface layers may be further formed on the other surface of the coating layer 120 to provide additional functions, such as anti-reflection, low reflection, hard coating, anti-glare, anti-fingerprint, anti-contamination, diffusion, and refraction functions, to the flexible window film. The functional layers may be formed as discrete layers independent of the coating layer 120 or may be formed by forming roughness on one surface of the coating layer 120 such that the one surface of the coating layer 120 acts as a functional layer. In addition, although not shown in FIG. 1, the coating layer 120 may further be formed on the other surface of the base layer 110. In one embodiment, the coating layer 120 may be formed of the composition for window films according to the embodiments of the present invention.

The flexible window film 100 is optically transparent. Specifically, the flexible window film 100 may have a light transmittance of about 88% or more, specifically about 88% to about 100%, in the visible range, specifically in a wavelength range of 400 nm to 800 nm. The flexible window film 100 may have a thickness of about 50 μm to about 300 μm. Within these ranges of light transmittance and thickness, the flexible window film can be used in a flexible display.

The flexible window film 100 may have a pencil hardness of about 6H or higher, a radius of curvature of about 5.0 mm or less, an inverse radius of curvature of about 20 mm or less, and a curl of 5.0 mm or less. Within these ranges, the flexible window film has good properties in terms of hardness, flexibility, and inverse radius of curvature and has low curl to be suitably used as a flexible window film. Specifically, the flexible window film 100 may have a pencil hardness of about 6H to about 9H, a radius of curvature of about 0.1 mm to about 5.0 mm, an inverse radius of curvature of about 3 mm to about 15 mm, and a curl of about 0.1 mm to about 5.0 mm.

Next, a flexible window film according to another embodiment will be described with reference to FIG. 2. FIG. 2 is a sectional view of a flexible window film according to another embodiment of the invention. The flexible window film according to this embodiment is substantially the same as the flexible window film according to the above embodiment except that the flexible window film according to this embodiment further includes an adhesive layer. Thus, the following description will focus on the adhesive layer.

The adhesive layer 130 is formed on the other surface of the base layer 110 to facilitate adhesion between the flexible window film and a touchscreen panel, a polarizing plate or a display part. The adhesive layer 130 may be formed of, for example, a typical adhesive composition including an adhesive resin, such as a (meth)acrylic resin, a urethane resin, a silicone resin, and an epoxy resin, a curing agent, a photoinitiator, and a silane coupling agent. The (meth)acrylic resin is a (meth)acrylic copolymer having an alkyl group, a hydroxyl group, an aromatic group, a carboxylic acid group, an alicyclic group, or a hetero-alicyclic group, and may include any typical (meth)acrylic copolymer. Specifically, the (meth)acrylic resin may be formed of a monomer mixture including at least one of a (meth)acrylic monomer containing a C₁ to C₁₀ unsubstituted alkyl group, a (meth)acrylic monomer containing a C₁ to C₁₀ alkyl group having at least one hydroxyl group, a (meth)acrylic monomer containing a C₆ to C₂₀ aromatic group, a (meth)acrylic monomer containing a carboxylic acid group, a (meth)acrylic monomer containing a C₃ to C₂₀ alicyclic group, and a (meth)acrylic monomer containing a C₃ to C₁₀ hetero-alicyclic group having at least one of nitrogen (N), oxygen (O), and sulfur (S). The curing agent is a polyfunctional (meth)acrylate and may include: bifunctional (meth)acrylates such as hexanediol diacrylate; trifunctional (meth)acrylates such as trimethylolpropane tri(meth)acrylate; tetrafunctional (meth)acrylates such as pentaerythritol tetra(meth)acrylate; pentafunctional (meth)acrylates such as dipentaerythritol penta(meth)acrylate; and hexafunctional (meth)acrylates such as dipentaerythritol hexa(meth)acrylate, without being limited thereto. The photoinitiator is a typical photoinitiator and may include the photoradical initiator described above. The silane coupling agent may include an epoxy group-containing silane coupling agent such as 3-glycidoxypropyltrimethoxysilane. The adhesive composition may include 100 parts by weight of the (meth)acrylic resin, about 0.1 parts by weight to about 30 parts by weight of the curing agent, about 0.1 parts by weight to about 10 parts by weight of the photoinitiator, and about 0.1 parts by weight to about 20 parts by weight of the silane coupling agent. Within these ranges, the flexible window film can have good adhesion to a display part, a touchscreen panel or a polarizing plate. The adhesive layer 130 may have a thickness of about 10 μm to about 100 μm. Within this range, the flexible window film can have sufficient adhesion to an optical device such as a polarizing plate.

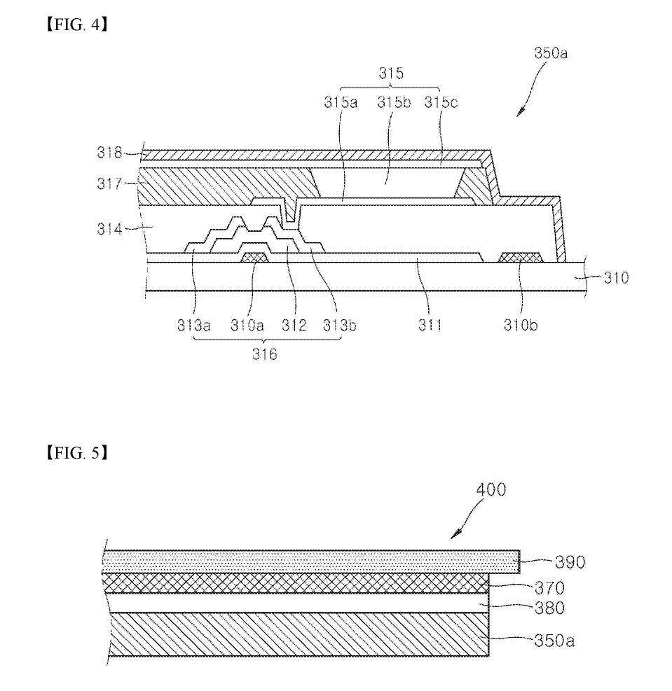

Next, a flexible display according to one embodiment of the present invention will be described with reference to FIG. 3 and FIG. 4. FIG. 3 is a sectional view of a flexible display according to one embodiment of the present invention and FIG. 4 is a sectional view of one embodiment of a display part shown in FIG. 3.

Referring to FIG. 3, a flexible display 300 according to one embodiment of the invention includes a display part 350a, an adhesive layer 360, a polarizing plate 370, a touchscreen panel 380, and a flexible window film 390, which may include the flexible window film according to the embodiments of the invention.

The display part 350a serves to drive the flexible display 300 and may include a substrate and an optical device formed on the substrate and including an OLED, an LED or an LCD device. FIG. 4 is a sectional view of one embodiment of the display part shown in FIG. 3. Referring to FIG. 4, the display part 350a includes a lower substrate 310, a thin film transistor 316, an organic light emitting diode 315, a flattening layer 314, a protective layer 318, and an insulating layer 317.

The lower substrate 310 supports the display part 350a, and the thin film transistor 316 and the organic light emitting diode 315 may be formed on the lower substrate 310. The lower substrate 310 may be formed with a flexible printed circuit board (FPCB) for driving the touchscreen panel 380. The flexible printed circuit board may further include a timing controller, a power source, and the like in order to drive an array of organic light emitting diodes.

The lower substrate 310 may include a substrate formed of a flexible resin. Specifically, the lower substrate 310 may include a flexible substrate such as a silicon substrate, a polyimide substrate, a polycarbonate substrate, and a polyacrylate substrate, without being limited thereto.

In a display region of the lower substrate 310, plural pixel domains are defined by plural driving wires (not shown) and plural sensor wires (not shown) intersecting each other, and an array of organic light emitting diodes each including the thin film transistor 316 and the organic light emitting diode 315 connected to the thin film transistor 316 may be formed in each of the pixel domains. In a non-display region of the lower substrate, a gate driver may take the form of a gate-in-panel to apply electrical signals to the driving wires. A gate-in-panel circuit may be formed at one or both sides of the display region.

The thin film transistor 316 controls electric current flowing through a semiconductor by application of an electric field perpendicular thereto and may be formed on the lower substrate 310. The thin film transistor 316 may include a gate electrode 310a, a gate insulation layer 311, a semiconductor layer 312, a source electrode 313a, and a drain electrode 313b. The thin film transistor 316 may be an oxide thin film transistor using an oxide, such as indium gallium zinc oxide (IGZO), ZnO, or TiO, as the semiconductor layer 312, an organic thin film transistor using an organic material as the semiconductor layer, an amorphous silicon thin film transistor using amorphous silicon as the semiconductor layer, or a polycrystalline silicon thin film transistor using polycrystalline silicon as the semiconductor layer.

The flattening layer 314 covers the thin film transistor 316 and the circuit 310b to flatten upper surfaces of the thin film transistor 316 and the circuit 310b such that the organic light emitting diode 315 can be formed thereon. The flattening layer 314 may be formed of a spin-on-glass (SOG) film, a polyimide polymer, or a polyacrylic polymer, without being limited thereto.

The organic light emitting diode 315 realizes a display through self-emission, and may include a first electrode 315a, an organic light-emitting layer 315b, and a second electrode 315c, which are stacked in the stated order. Adjacent organic light emitting diodes may be isolated from each other by the insulating layer 317. The organic light emitting diode 315 may have a bottom emission structure in which light from the organic light emitting layer 315b is discharged through the lower substrate or may have a top emission structure in which light from the organic light emitting layer 315b is discharged upward.

The protective film 318 covers the organic light emitting diodes 315 to protect the organic light emitting diodes 315. The protective film 318 may be formed of an inorganic material such as SiOₓ, SiNₓ, SiC, SiON, SiONC, amorphous carbon (a-C), or an organic material such as (meth)acrylates, epoxy polymers, and imide polymers. Specifically, the protective layer 318 may include an encapsulation layer in which an inorganic material layer and an organic material layer are sequentially stacked once or plural times.

Referring again to FIG. 3, the adhesive layer 360 attaches the display part 350a to the polarizing plate 370 and may be formed of an adhesive composition including a (meth)acrylate resin, a curing agent, an initiator, and a silane coupling agent.

The polarizing plate 370 can realize polarization of internal light or prevent reflection of external light to realize a display, or can increase contrast of the display. The polarizing plate may be composed of a polarizer alone. Alternatively, the polarizing plate may include a polarizer and a protective film formed on one or both surfaces thereof. Alternatively, the polarizing plate may include a polarizer and a protective coating layer formed on one or both surfaces thereof. As the polarizer, the protective film and the protective coating layer, a typical polarizer, a typical protective film and a typical protective coating layer known in the art may be used.

The touchscreen panel 380 generates electrical signals through detection of variation in capacitance when a human body or a conductor such as a stylus touches the touchscreen panel, and the display part 350a may be driven by such electrical signals. The touchscreen panel 380 is formed by patterning a flexible conductor, and may include first sensor electrodes and second sensor electrodes each formed between the first sensor electrodes and intersecting the first sensor electrodes. The touchscreen panel 380 may include a conductive material such as metal nanowires, conductive polymers, and carbon nanotubes, without being limited thereto.

The flexible window film 390 may be disposed at the outermost side of the flexible display 300 to protect the flexible display.

Although not shown in FIG. 3, adhesive layers may further be formed between the polarizing plate 370 and the touchscreen panel 380 and/or between the touchscreen panel 380 and the flexible window film 390 to reinforce coupling between the polarizing plate, the touchscreen panel, and the flexible window film. The adhesive layers may be formed of an adhesive composition including a (meth)acrylate resin, a curing agent, an initiator, and a silane coupling agent. Although not shown in FIG. 3, a polarizing plate may be further disposed under the display part 350a to realize polarization of internal light.

Next, a flexible display according to another embodiment of the present invention will be described with reference to FIG. 5. FIG. 5 is a sectional view of a flexible display according to another embodiment of the present invention.

Referring to FIG. 5, a flexible display 400 according to this embodiment is substantially the same as the flexible display according to the above embodiment except that the touchscreen panel 380 is disposed under the polarizing plate 370 instead of being directly disposed on the flexible window film 390. In addition, the touchscreen panel 380 may be formed together with the display part 350a. In this case, since the touchscreen panel 380 is formed together with the display part 350a on the display part 350a, the flexible display according to this embodiment is thinner and brighter than the flexible display according to the above embodiment, thereby providing better visibility. Furthermore, the touchscreen panel 380 may be formed by deposition, without being limited thereto. Although not shown in FIG. 5, adhesive layers may be further formed between the display part 350a and the touchscreen panel 380, between the touchscreen panel 380 and the polarizing plate 370, and/or between the polarizing plate 370 and the flexible window film 390 to reinforce mechanical strength of the display. Although not shown in FIG. 5, a polarizing plate may be further disposed under the display part 350a to provide a good display image through polarization of internal light.

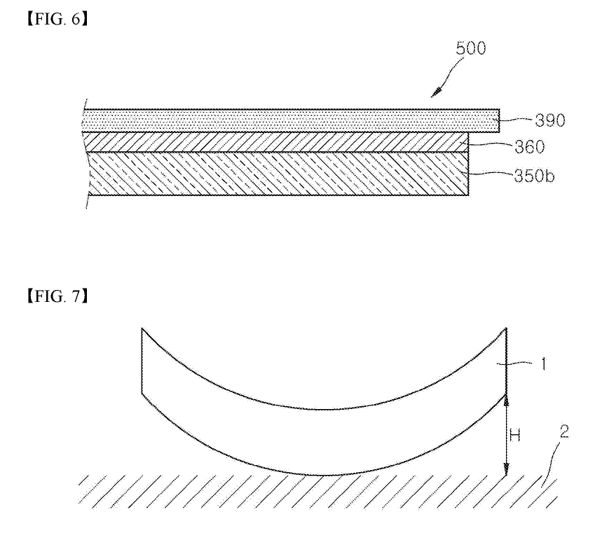

Next, a flexible display according to a further embodiment of the present invention will be described with reference to FIG. 6. FIG. 6 is a sectional view of a flexible display according to a further embodiment of the present invention. Referring to FIG. 6, a flexible display 500 according to this embodiment is substantially the same as the flexible display according to the embodiment except that the flexible display includes a display part 350b and does not include the polarizing plate 370 and the touchscreen panel 380. The display part 350a may include a substrate and an optical device formed on the substrate and including an OLED, an LED or an LCD device. The display part 350b may further include a touchscreen panel therein.

Although the flexible window films according to the embodiments are illustrated as being applied to a flexible display, it should be understood that the flexible window films according to the embodiments may also be applied to a non-flexible display.

Next, a method of preparing the siloxane resin represented by Formula 1 will be described.

The siloxane resin of Formula 1 may be formed of a monomer mixture including a first silicone monomer, a second silicone monomer, and a third silicone monomer. In the monomer mixture, the first silicone monomer may be present in an amount of about 30 mol % to about 90 mol %, specifically about 40 mol % to about 85 mol %, more specifically about 40 mol % to about 70 mol %; the second silicone monomer may be present in an amount of about 1 mol % to about 50 mol %, specifically about 5 mol % to about 50 mol %, more specifically about 20 mol % to about 40 mol %, about 5 mol % to about 50 mol %, about 5 mol % to about 40 mol %, or about 5 mol % to about 30 mol %; and the third silicone monomer may be present in an amount of about 1 mol % to about 40 mol %, specifically about 1 mol % to about 35 mol %, more specifically about 5 mol % to about 35 mol %, about 1 mol % to about 30 mol %, about 5 mol % to about 35 mol %, about 10 mol % to about 35 mol %, or about 10 mol % to about 30 mol %. Within these ranges, the window film can secure high hardness, good flexibility, low curl, and low inverse radius of curvature and is free from indentation. The first silicone monomer, the second silicone monomer and the third silicone monomer may be represented by Formula 2, Formula 3, and Formula 4, respectively, and may be used alone or as a mixture thereof:

Si(R¹)(R³)(R⁴)(R⁵) <Formula 2>

Si(R²)(R⁶)(R⁷)(R⁸) <Formula 3>

Si(R⁹)(R¹⁰)(R¹¹)(R¹²) <Formula 4>

(wherein Formula 2, Formula 3 and Formula 4, R¹ and R² are as defined in Formula 1; R³, R⁴, R⁵, R⁶, R⁷, R⁸, R⁹, R¹⁰, R¹¹ and R¹² are each independently a halogen atom, a hydroxyl group or a C₁ to C₁₀ alkoxy group).

Specifically, the first silicone monomer may include at least one of 2-(3,4-epoxycyclohexyl)ethyltriethoxysilane, and 2-(3,4-epoxycyclohexyl)ethyltrimethoxysilane; the second silicone monomer may include at least one of 3-glycidoxypropyltrimethoxysilane and 3-glycidoxypropyltriethoxysilane; and the third silicone monomer may include at least one of tetramethoxysilane and tetraethoxysilane, without being limited thereto.

The siloxane resin represented by Formula 1 may be prepared by hydrolysis and condensation of the monomer mixture. Hydrolysis and condensation of the monomer mixture may be performed by any typical method. Hydrolysis of the monomer mixture may include reacting the monomer mixture with a mixture of water and a certain base. Specifically, the base may include a strong base such as NaOH and KOH. The base may be present in an amount of less than about 2 mol %, for example, about 0.01 mol % to about 1 mol %, in the monomer mixture of the silicone monomers. Hydrolysis and condensation of the monomer mixture may be carried out at about 20° C. to about 100° C. for about 10 minutes to about 12 hours under. Under these conditions, hydrolysis and condensation of the monomer mixture can be efficiently performed.

Next, a method of preparing a flexible window film according to one embodiment of the present invention will be described.

The flexible window film 100 may be formed by coating the composition for window films according to the embodiments to a predetermined thickness on the base layer 110, followed by curing.

A method of coating the composition for window films onto the base layer is not particularly limited. For example, the composition may be coated onto the base layer by bar coating, spin coating, dip coating, roll coating, flow coating, or die coating. The composition may be coated to a thickness of 5 μm to 100 μm on the base layer. Within this thickness range, a desired coating layer can be secured while providing good hardness and flexibility. Curing may be performed by at least one of photo-curing and thermal curing. Photo-curing may be performed through UV irradiation at a fluence of about 10 mJ/cm² to about 1000 mJ/cm² at a wavelength of about 400 nm or less. Thermal curing may be performed at about 40° C. to about 200° C. for about 1 to 30 hours. Under these conditions, the composition for window films can be sufficiently cured. Thermal curing may be performed after photo-curing in order to achieve higher hardness of the coating layer. Before curing the composition for window films coated onto the base layer 110, the composition may be subjected to drying to prevent increase in surface roughness of the coating layer due to photo-curing or thermal curing for a long period of time. Drying may be performed at 40° C. to 200° C. for 1 minute to 30 hours, without being limited thereto.

Next, the present invention will be described in more detail with reference to some examples. It should be understood that these examples are provided for illustration only and are not to be in any way construed as limiting the present invention.

### Example 1

Into a 500 ml 2-neck flask, 100 g of a monomer mixture comprising 2-(3,4-epoxycyclohexyl)ethyltrimethoxysilane (KBM-303, Shin-Etsu Chemical), (3-glycidoxypropyl)trimethoxysilane (KBM-403, Shin-Etsu Chemical) and tetraethoxysilane (Samchun Chemical) was placed in amounts (mol %) as listed in Table 1. Then, 0.5 mol % of KOH (based on the monomer mixture) and 70 mol % of water (based on the total amount of an alkoxy group in the monomer mixture) were added to the monomer mixture, which in turn was stirred at 65° C. for 2 hours and washed with toluene, followed by removing the remaining solvent from the resulting product using a vacuum distiller, thereby preparing a siloxane resin (weight average molecular weight as measured by GPC: 8,000).

Then, 100 parts by weight of the prepared siloxane resin was mixed with 10 parts by weight of 3,4-epoxycyclohexylmethyl 3′,4′-epoxycyclohexanecarboxylate as a crosslinking agent, 3 parts by weight of a photoinitiator (Irgacure-250, BASF), and methylethylketone as a solvent, thereby preparing a composition for window films (solid content: 70%). The prepared composition was coated onto a polyimide film (thickness: 50 μm) using a Meyer bar and dried at 80° C. for 5 minutes, followed by UV irradiation at a fluence of 1000 mJ/cm² and heat treatment at 100° C. for 24 hours, thereby preparing a window film including a coating layer having a thickness of 50 μm.

### Examples 2 and 3 and Comparative Examples 1 to 5

Window films were prepared in the same manner as in Example 1 except that the contents of the silicon monomers were changed as listed in Table 1.

The components of the composition for window films prepared in Examples and Comparative Examples are shown in Table 1. Each of the window films prepared in Examples and Comparative Examples was evaluated as to the following properties. Results are shown in Table 1.

(1) Pencil hardness: Pencil hardness was measured on a coating layer of each of the window films using a pencil hardness tester (Heidon Co., Ltd.) in accordance with JIS K5400. Pencil hardness was measured using pencils of 6B to 9H (Mitsubishi Co., Ltd.). Specifically, pencil hardness was measured under a load of 1 kg on the coating layer at a scratch angle of 45° and a scratch speed of 60 mm/min. When the coating layer had one or more scratches after being tested 5 times using a certain pencil, pencil hardness was measured again using another pencil having one-level lower pencil hardness than the previous pencil. A pencil hardness value allowing no scratch to be observed all five times on the coating layer was taken as pencil hardness of the coating layer.

(2) Radius of curvature: Each of window film specimens (width×length×thickness: 3 cm×15 cm×100 μm, Thickness of base layer: 50 μm, Thickness of coating layer: 50 μm) was wound around a jig for measurement of radius of curvature (CFT-200R, COVOTECH Co., Ltd.) such that the coating layer contacted the jig, was kept wound for 5 seconds, unwound, and then observed with the naked eye to determine whether the specimen had cracks. Here, the minimum radius of a jig causing no cracks in the specimen was obtained. When the minimum radius capable of being measured by this method was 2 mm and a curved surface of the window film folded in half without damage had a radius of less than 3 mm, 3 mm or less was determined as the resulting value.

(3) Inverse radius of curvature: Each of window film specimens (width×length×thickness: 3 cm×15 cm×100 μm, Thickness of base layer: 50 μm, Thickness of coating layer: 50 μm) was wound around the jig (CFT-200R, COVOTECH Co., Ltd.) such that the base layer contacted the jig, was kept wound for 5 seconds, and then observed with the naked eye to determine whether the window film had cracks. The inverse radius of curvature was determined by a minimum radius of a jig causing no cracks in the specimen, as measured while gradually decreasing the diameters of jigs through replacement of the jigs. When the minimum radius capable of being measured by this method was 2 mm and a curved surface of a film folded in half without damage had a radius of less than 3 mm, 3 mm or less was determined as the resulting radius of curvature of the film.

(4) Indentation: After measurement of pencil hardness by the method as described in (1), an indentation was observed together with the presence of scratches on the coating layer at the corresponding pencil hardness. The presence of an indentation together with scratches was rated as ∘ and the absence of an indentation was rated as x.

(5) Curl: Referring to FIG. 7, each of the flexible window films 1 was cut to a size of 10 cm×10 cm (width×length) and then left on a floor surface 2 at 25° C. and 40% RH, followed by measurement of a maximum height (H) of an edge of the window film from the floor surface 2, and then the measured values were averaged.

TABLE 1

| | | | | | Comparative | Comparative | Comparative | Comparative | Comparative |
|---|---|---|---|---|---|---|---|---|---|
| | | Example 1 | Example 2 | Example 3 | Example 1 | Example 2 | Example 3 | Example 4 | Example 5 |
| Silicone | 2-(3,4-epoxycyclohexyl)ethyl- | 85 | 50 | 40 | 100 | 0 | 90 | 30 | 20 |
| monomer | trimethoxysilane | | | | | | | | |
| (mol %) | 3-glycidoxypropyl- | 5 | 30 | 30 | 0 | 100 | 0 | 20 | 60 |
| | trimethoxysilane | | | | | | | | |
| | Tetraethoxysilane | 10 | 20 | 30 | 0 | 0 | 10 | 50 | 20 |
| Siloxane | x in Formula 1-1 | 0.85 | 0.50 | 0.40 | 1.0 | 0 | 0.90 | 0.30 | 0.20 |
| resin | y in Formula 1-1 | 0.05 | 0.30 | 0.30 | 0 | 1.0 | 0 | 0.20 | 0.60 |
| | z in Formula 1-1 | 0.10 | 0.20 | 0.30 | 0 | 0 | 0.10 | 0.50 | 0.20 |
| | Weight average | 8 | 7.6 | 8.0 | 5.2 | 7.2 | 6.5 | 5 | 7.7 |
| | molecular weight | | | | | | | | |
| | (×10³) | | | | | | | | |

| | | | | | | | | |
|---|---|---|---|---|---|---|---|---|
| Crosslinking agent | 10 | 10 | 10 | 10 | 10 | 10 | 10 | 10 |
| (parts by weight) | | | | | | | | |
| Initiator | 3 | 3 | 3 | 3 | 3 | 3 | 3 | 3 |
| (parts by weight) | | | | | | | | |
| Pencil hardness | 8H | 8H | 8H | 8H | 6H | 8H | 8H | 8H |
| Radius of curvature | 3 | 3 | 3 | 3 | 3 | 5 | 10 | 3 |
| (mm) | | | | | | | | |
| Inverse radius of curvature | 10 | 12 | 12 | 22 | 10 | 26 | bendingx** | 10 |
| (mm) | | | | | | | | |
| Indentation Curl | x | x | x | ∘ | ∘ | x | x | x |
| (mm) | 0 | 3 | 4 | 0 | roll* | 3 | 10 | roll* |

*roll: A window film specimen was completely wound.
**bendingx: A window film specimen could not be bent.

As shown in Table 1, the flexible window films prepared in Examples exhibited good properties in terms of hardness, flexibility, and indentation characteristics, and had low inverse radii of curvature and low curl lengths. On the contrary, the window film of Comparative Example 1 including a siloxane resin formed of 2-(3,4-epoxycyclohexyl)ethyltrimethoxysilane alone exhibited poor properties in terms of inverse radius of curvature and indentation characteristics, and the window film of Comparative Example 2 including a siloxane resin formed of 3-glycidoxypropyltrimethoxysilane exhibited poor properties in terms of curl and indentation characteristics. In addition, the window films of Comparative Examples 1 and 2 free from tetraethoxysilane exhibited poor indentation characteristics. The window films of Comparative Examples 3 to 5 prepared using siloxane resins comprising the silicone monomers outside the content range set forth herein had a high inverse radius of curvature or suffered from significant curling.

It should be understood that various modifications, changes, alterations, and equivalent embodiments can be made by those skilled in the art without departing from the spirit and scope of the present invention.

1. A composition for window films, comprising:
a siloxane resin represented by Formula 1; a crosslinking agent; and an initiator:
(R¹SiO_{3/2})ₓ(R²SiO_{3/2})_{y}(SiO_{4/2})_{z} <Formula 1>
(where, in Formula 1, R¹ is an alicyclic epoxy group or an alicyclic epoxy group-containing functional group; R² is a glycidyl group or a glycidyl group-containing functional group; and x, y and z are set to satisfy about 0.30≤x≤about 0.90, about 0.01≤y≤about 0.50, about 0.01≤z≤about 0.40, and x+y+z=1).

2. The composition for window films according to claim 1, wherein the siloxane resin is represented by Formula 1-1:
(EcSiO_{3/2})ₓ(GpSiO_{3/2})_{y}(SiO_{4/2})_{z} <Formula 1-1>
(where, in Formula 1-1, Ec is a 2-(3,4-epoxycyclohexyl)ethyl group; Gp is a 3-glycidoxypropyl group; and x, y and z are set to satisfy about 0.30≤x≤about 0.90, about 0.01≤y≤about 0.50, about 0.01≤z≤about 0.40, and x+y+z=1).

3. The composition for window films according to claim 1, wherein the crosslinking agent comprises at least one of a non-cyclic aliphatic epoxy monomer, a cyclic aliphatic epoxy monomer, an aromatic epoxy monomer, a hydrogenated aromatic epoxy monomer, and an oxetane monomer.

4. A flexible window film comprising a base layer and a coating layer formed on one surface of the base layer,
wherein the coating layer is formed of a composition comprising a siloxane resin represented by Formula A and has a pencil hardness of about 6H or higher and a radius of curvature of about 5.0 mm or less:
(R¹SiO_{3/2})ₓ(R²SiO_{3/2})_{y}(SiO_{4/2})_{z} <Formula A>
(where, in Formula A, R¹ is an alicyclic epoxy group or an alicyclic epoxy group-containing functional group; R² is a glycidyl group or a glycidyl group-containing functional group; and x, y and z are set to satisfy about 0.30≤x≤about 0.90, about 0.01≤y≤about 0.50, about 0.01≤z≤about 0.40, and x+y+z=1).

5. The flexible window film according to claim 4, wherein the composition comprises:
a siloxane resin represented by Formula 1; a crosslinking agent; and an initiator:
(R¹SiO_{3/2})ₓ(R²SiO_{3/2})_{y}(SiO_{4/2})_{z} <Formula 1>
(where, in Formula 1, R¹ is an alicyclic epoxy group or an alicyclic epoxy group-containing functional group; R² is a glycidyl group or a glycidyl group-containing functional group; and x, y and z are set to satisfy about 0.30≤x≤about 0.90, about 0.01≤y≤about 0.50, about 0.01≤z≤about 0.40, and x+y+z=1).

6. The flexible window film according to claim 4, further comprising: an adhesive layer formed on the other surface of the base layer.

7. A flexible display comprising the flexible window film according to claim 4.

8. The flexible display according to claim 7, comprising: a display part; an adhesive layer formed on the display part; a polarizing plate formed on the adhesive layer; a touchscreen panel formed on the polarizing plate; and the flexible window film formed on the touchscreen panel.

9. The flexible display according to claim 7, comprising: a display part; a touchscreen panel formed on the display part; a polarizing plate formed on the touchscreen panel; and the flexible window film formed on the polarizing plate.

10. The flexible display according to claim 7, comprising: a display part; an adhesive layer formed on the display part; and the flexible window film formed on the adhesive layer.

11. The flexible display according to claim 10, wherein the display part further comprises a polarizing plate formed on an upper or lower surface thereof.
